(19) United States
(12) Patent Application Publication
(10) Pub. No.: US 2018/0237914 A1
(43) Pub. Date: Aug. 23, 2018

(54) FILM FORMING APPARATUS

(71) Applicant: TOKYO ELECTRON LIMITED, Tokyo (JP)

(72) Inventors: Jun OGAWA, Nirasaki City (JP); Noriaki FUKIAGE, Nirasaki City (JP); Shimon OTSUKI, Oshu City (JP); Muneyuki OTANI, Nirasaki City (JP); Kentaro OSHIMO, Nirasaki City (JP); Hideomi HANE, Nirasaki City (JP)

(21) Appl. No.: 15/897,209

(22) Filed: Feb. 15, 2018

(30) Foreign Application Priority Data
Feb. 20, 2017 (JP) 2017-029366

(51) Int. Cl. C23C 16/455; C23C 16/513; C23C 16/458; H01L 21/02; H01L 21/67; H01L 21/687

(52) U.S. Cl. CPC C23C 16/45544; C23C 16/513; C23C 16/4584; H01L 21/68764; H01L 21/0217; H01L 21/67017; H01L 21/68771; H01L 21/0228

(57) ABSTRACT

An apparatus for forming a nitride film of a raw material component on a substrate, includes: a raw material gas supply part having discharge ports that discharge a raw material gas and a purge gas, and an exhaust port; a reaction region spaced apart from the raw material gas supply part in a circumferential direction of a rotary table; a modification region spaced apart from the reaction region in the circumferential direction and in which the nitride film is modified with a hydrogen gas; a first plasma generating part provided in the modification region and a second plasma generating part provided in the reaction region, and for activating a gas existing in each of the modification and reaction regions; a reaction gas supply part for supplying the ammonia gas to the reaction region; and an exhaust port that evacuates an interior of the vacuum vessel.

### CROSS-REFERENCE TO RELATED APPLICATION

This application is based upon and claims the benefit of priority from Japanese Patent Application No. 2017-029366, filed on Feb. 20, 2017, the entire contents of which are incorporated herein by reference.

### TECHNICAL FIELD

The present disclosure relates to a film forming apparatus for forming a nitride film of a raw material component on a substrate using a raw material gas containing the raw material component and an ammonia gas.

### BACKGROUND

In a semiconductor manufacturing process, a film forming process is carried out which forms a silicon nitride film (which is sometimes abbreviated as an “SiN film” hereinafter), for example, as a hard mask in an etching process, on a substrate. The SiN film of this disclosure is required to have a low etching rate and plasma resistance against, for example, a hydrofluoric acid solution, and thus is required to have a high density. Further, a deposition rate in the plane of a substrate varies depending on a pattern structure or pattern density, which may cause a phenomenon called a loading effect in which the thickness of the SiN film as formed varies in the plane of the substrate. Thus, the improvement of the loading effect is required.

For example, a film forming apparatus which forms an SiN film by atomic layer deposition (ALD) is known. In this film forming apparatus, a mounting table is rotated (revolved) about an axial line inside a process chamber so that a substrate mounting region formed in the mounting table sequentially passes through a first region and a second region defined inside the process chamber, to perform a film forming process. In the first region, a dichlorosilane (DCS) gas is supplied from injection portions of a first gas supply part and Si is adsorbed onto a substrate, and the unnecessary DCS gas is exhausted from an exhaust port formed so as to surround the injection portions. In the second region, four plasma generating parts are positioned along the rotational direction. Then, in these plasma generating parts, a nitrogen (N₂) gas or an ammonia (NH₃) gas, which is a reaction gas, is supplied and the gas is excited so that Si adsorbed onto the substrate is nitrided by active species of the reaction gas. As a result, the SiN film is formed.

Although a dense SiN film is formed by such ALD, when it is used as, for example, a hard mask, depending on the intended use, the denseness of the film is required to be further increased and high uniformity of film thickness is required. Therefore, there is a demand for a film forming method that can form a high-quality SiN film with high denseness while improving the loading effect.

### SUMMARY

The present disclosure provides some embodiments of a technique capable of forming a high-quality nitride film while improving (suppressing) a loading effect, in forming a nitride film of a raw material component using a raw material gas containing the raw material component and an ammonia gas.

According to one embodiment of the present disclosure, there is provided a film forming apparatus for forming a nitride film of a raw material component on a substrate inside a vacuum vessel by revolving a rotary table on which the substrate is disposed and supplying a raw material gas containing the raw material component and an ammonia gas used as a reaction gas to regions separated from each other in a circumferential direction of the rotary table, the apparatus including: a raw material gas supply part facing the rotary table, and having a first discharge port that discharges the raw material gas, an exhaust port that surrounds the first discharge port and a second discharge port that surrounds the exhaust port and discharges a purge gas; a reaction region spaced apart from the raw material gas supply part in the circumferential direction of the rotary table and in which the nitride film is nitrided; a modification region spaced apart from the reaction region in the circumferential direction of the rotary table, and in which the nitride film is modified with a hydrogen gas; a first plasma generating part provided in the modification region and a second plasma generating part provided in the reaction region, and configured to activate a gas existing in each of the modification region and the reaction region; a reaction gas supply part configured to supply the ammonia gas to the reaction region; and an exhaust port configure to evacuate an interior of the vacuum vessel, wherein a flow rate of the hydrogen gas supplied to the modification region is greater than 0 and not more than 0.1 l/min

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic longitudinal sectional view of a film forming apparatus according to an embodiment of the present disclosure.

FIG. 2 is a traverse plan view of the film forming apparatus.

FIG. 3 is a bottom view of a gas supply/exhaust unit positioned in the film forming apparatus.

FIG. 4 is a characteristic view showing an etching rate.

FIGS. 5A and 5B are characteristic views showing a hydrogen concentration and a chlorine concentration in an SiN film.

FIGS. 6A and 6B are characteristic views showing a film thickness of an SiN film and a loading effect.

FIG. 7 is a characteristic view showing a loading effect.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

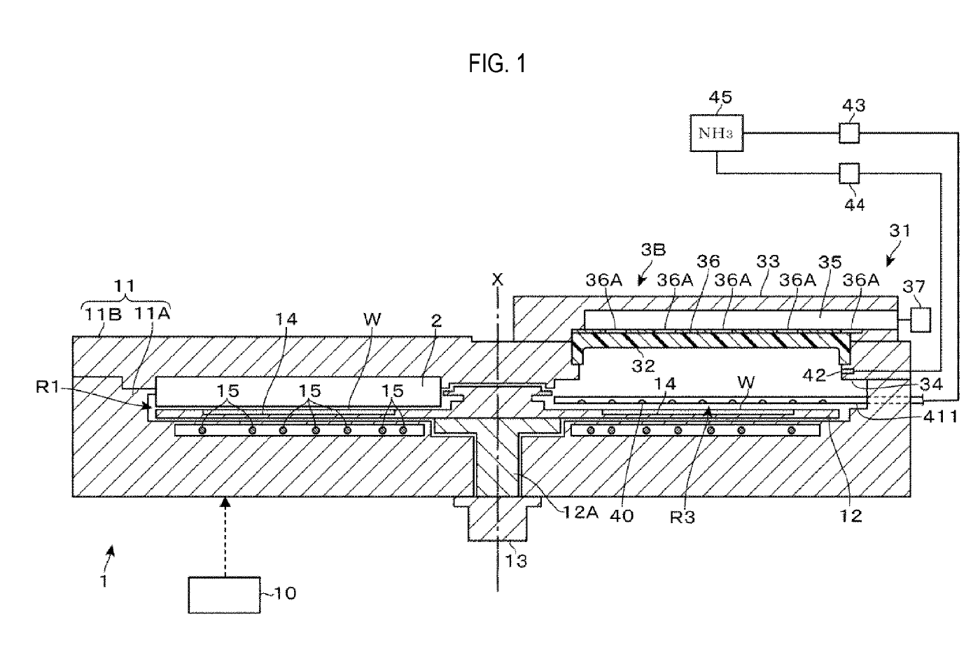

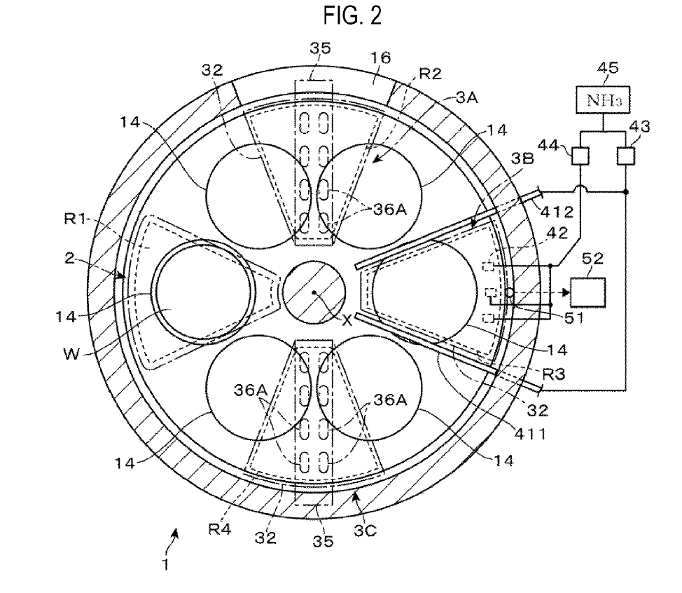

A film forming apparatus 1 according to an embodiment of the present disclosure will be described with reference to a longitudinal sectional view of FIG. 1 and a traverse plan view of FIG. 2, respectively. In this film forming apparatus 1, an SiN film is formed on a surface of a semiconductor wafer (hereinafter, referred to as a “wafer”) W as a substrate by atomic layer deposition (ALD). The SiN film serves as, for example, a hard mask in an etching process. Herein, the silicon nitride film will be described as SiN, regardless of the stoichiometric ratio of Si and N. Therefore, the description of SiN includes, for example, Si₃N₄.

In FIG. 1, reference numeral 11 denotes a substantially-circular flat vacuum vessel (process vessel), which includes a vessel body 11A having a sidewall and a bottom portion, and a ceiling plate 11B. In FIG. 1, reference numeral 12 denotes a circular rotary table horizontally positioned inside the vacuum vessel 11. In FIG. 1, reference numeral 12A denotes a support part that supports the center of the rear surface of the rotary table 12. In FIG. 13, reference numeral 13 denotes a rotation mechanism, which rotates the rotary table 12 clockwise in a plan view in a circumferential direction through the support part 12A during a film forming process. In FIG. 1, reference symbol X represents a rotation axis of the rotary table 12.

Six circular recesses 14 are formed in an upper surface of the rotary table 12 along the circumferential direction (rotational direction) of the rotary table 12. For example, a 12-inch wafer W is accommodated in each of the recesses 14. That is to say, each wafer W is mounted on the rotary table 12 so as to revolve with the rotation of the rotary table 12. In FIG. 1, reference numeral 15 denotes heaters which are positioned concentrically in a bottom portion of the vacuum vessel 11 to heat the wafers W mounted on the rotary table 12. In FIG. 2, reference numeral 16 denotes a transfer port for the wafer W which is opened in the sidewall of the vacuum vessel 11, and is opened and closed by a gate valve (not shown). The wafers W are transferred between the outside of the vacuum vessel 11 and the insides of the recesses 14 via the transfer port 16 by a substrate transfer mechanism (not shown).

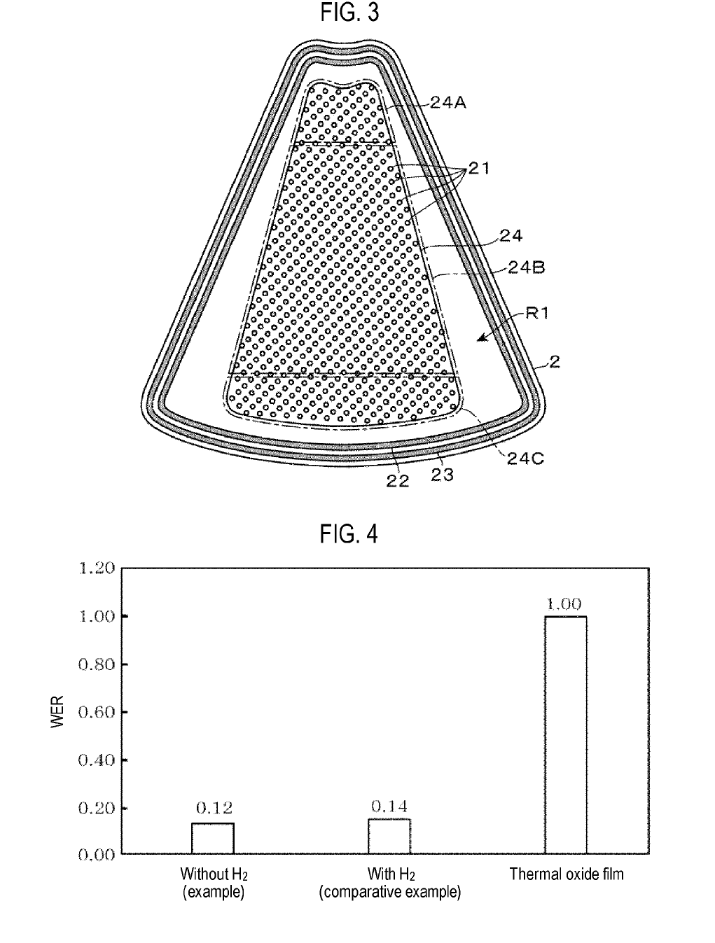

A gas supply/exhaust unit 2 constituting a raw material gas supply part, a first modification region R2, a reaction region R3, and a second modification region R4, are provided on the rotary table 12 toward a downstream side of the rotary table 12 in the rotational direction sequentially along the rotational direction. The gas supply/exhaust unit 2 corresponds to the raw material gas supply part having a discharge port for discharging a raw material gas therethrough and an exhaust port for exhausting the raw material gas therethrough, and a discharge port for discharging a purge gas therethrough. Hereinafter, the gas supply/exhaust unit 2 will be described with reference also to FIG. 3 which is a bottom view of the gas supply/exhaust unit 2. The gas supply/exhaust unit 2 is formed in a fan shape which widens in the circumferential direction of the rotary table 12 from the center of the rotary table 12 toward the peripheral side thereof in a plan view. The lower surface of the gas supply/exhaust unit 2 is close to and faces the upper surface of the rotary table 12.

A gas discharge port 21 constituting a discharge port, an exhaust port 22 and a purge gas discharge port 23 are opened in the lower surface of the gas supply/exhaust unit 2. In FIG. 3, in order to facilitate discrimination, each of the exhaust port 22 and the purge gas discharge port 23 is indicated by a plurality of dots. A plurality of gas discharge ports 21 are arranged in a fan-shaped region 24 inward of the peripheral edge of the lower surface of the gas supply/exhaust unit 2. The gas discharge ports 21 discharge a DCS gas, which is a raw material gas containing silicon (Si) for forming an SiN film, in a shower shape downward during the rotation of the rotary table 12 in the film forming process so that the DCS gas is supplied to the entire surface of the wafer W. The raw material gas containing silicon is not limited to DCS, and for example, hexachlorodisilane (HCD), tetrachlorosilane (TCS) or the like may also be used.

In the fan-shaped region 24, three sections 24A, 24B, and 24C are defined from the center of the rotary table 12 toward the peripheral side of the rotary table 12. Gas flow paths (not shown) which are partitioned from each other are formed in the gas supply/exhaust unit 2 so that the DCS gas can be supplied independently to the gas discharge ports 21 formed in the respective sections 24A, 24B, and 24C. Respective upstream sides of the gas flow paths partitioned from each other are connected to a supply source of the DCS gas via a pipe in which a gas supply device constituted by a valve and a mass flow controller is positioned. The illustration of the gas supply device, the pipe, and the supply source of the DCS gas will be omitted.

The exhaust port 22 and the purge gas discharge port 23 are annularly opened toward the upper surface of the rotary table 12 and around the peripheral edge of the lower surface of the gas supply/exhaust unit 2 so as to surround the fan-shaped region 24. The purge gas discharge port 23 is located outside the exhaust port 22. A region inward of the exhaust port 22 in the rotary table 12 forms an adsorption region R1 where DCS is adsorbed onto the surface of the wafer W. An exhaust device (not shown) is connected to the exhaust port 22. A supply source (not shown) of a purge gas, for example, an argon (Ar) gas, is connected to the purge gas discharge port 23.

During the film forming process, the discharge of the raw material gas from the gas discharge ports 21, the exhaust of the gas from the exhaust port 22 and the discharge of the purge gas from the purge gas discharge port 23 are simultaneously performed. Thus, the raw material gas and the purge gas discharged toward the rotary table 12 are directed to the exhaust port 22 and are exhausted from the exhaust port 22 toward the upper surface of the rotary table 12. By performing the discharge and the exhaust of the purge gas in this way, the internal atmosphere of the adsorption region R1 is separated from the external atmosphere so that the raw material gas can be limitedly supplied to the adsorption region RE That is to say, it is possible to suppress the DCS gas supplied to the adsorption region R1 from being mixed with a gas and active species of the gas supplied to the outside of the adsorption region R1 by a plasma forming unit 3B which will be described later. Thus, the ALD-based film forming process can be performed on the wafer W. In addition to such a role of separating the atmosphere, the purge gas also has a role of removing the DCS gas excessively adsorbed onto the wafer W therefrom.

A first plasma forming unit 3A, the second plasma forming unit 3B, and a third plasma forming unit 3C for activating gases existing in the respective regions are positioned in the first modification region R2, the reaction region R3, and the second modification region R4, respectively. The first plasma forming unit 3A constitutes a first plasma generating part, the second plasma forming unit 3B constitutes a plasma generating part for reaction gas, and the third plasma forming unit 3C constitutes a second plasma generating part.

The second plasma forming unit 3B will be described. The plasma forming unit 3B supplies a reaction gas onto the rotary table 12 and supplies a microwave to the reaction gas, thus generating plasma on the rotary table 12. The plasma forming unit 3B includes an antenna 31 for supplying the microwave. The antenna 31 includes a dielectric plate 32 and a metal waveguide 33.

The dielectric plate 32 is formed in a substantially fan shape which widens from the center to the periphery of the rotary table 12 in a plan view. A substantially fan-shaped through hole is formed in the ceiling plate 11B of the vacuum vessel 11 so as to correspond to the shape of the dielectric plate 32. In the through hole, the inner peripheral surface of the lower end portion of the ceiling plate 11B slightly protrudes toward the center of the through hole to form a support portion 34. The dielectric plate 32 closes the through hole from the upper side and is positioned so as to face the rotary table 12. A peripheral edge of the dielectric plate 32 is supported by the support portion 34.

The waveguide 33 is positioned on the dielectric plate 32 and has an internal space 35 extending along the radial direction of the rotary table 12. In FIG. 1, reference numeral 36 denotes a slot plate constituting the lower side of the waveguide 33, which is positioned so as to make contact with the dielectric plate 32. The slot plate 36 has a plurality of slot holes 36A formed therein. In FIG. 2, the slots 36A are omitted in the second plasma forming unit 3B. An end portion of the waveguide 33 at the center of the rotary table 12 is closed. The other end portion of the waveguide 33 at the periphery of the rotary table 12 is connected to a microwave generator 37. The microwave generator 37 supplies a microwave of, e.g., about 2.45 GHz, to the waveguide 33.

As illustrated in FIGS. 1 and 2, reaction gas injectors 411 and 412 which respectively supply an ammonia (NH₃) gas as a reaction gas are positioned below the second plasma forming unit 3B. For example, one of the reaction gas injectors 411 and 412 is positioned near the downstream side of the second plasma forming unit 3B in the rotational direction, and the other is positioned near the upstream side of the second plasma forming unit 3B in the rotational direction. The reaction gas injectors 411 and 412 are formed in, for example, an elongated tubular body with its leading end closed. The reaction gas injectors 411 and 412 are respectively positioned in the sidewall of the vacuum vessel 11 so as to horizontally extend from the sidewall of the vacuum vessel 11 toward the central region thereof and to cross a region through which the wafers W mounted on the rotary table 12 pass. In addition, gas discharge ports 40 are respectively formed in the reaction gas injectors 411 and 412 along its longitudinal direction.

Furthermore, the second plasma forming unit 3B has a plurality of gas discharge ports 42 that supplies an ammonia (NH₃) gas as a reaction gas to the lower surface side of the dielectric plate 32. The plurality of gas discharge ports 42 is formed in the support portion 34 of the dielectric plate 32, for example, along the circumferential direction of the vacuum vessel 11, and is respectively configured to discharge the reaction gas from the periphery of the rotary table 12 toward the center thereof. The combination of the reaction gas injectors 411 and 412 and the gas discharge ports 42 constitutes a reaction gas supply part.

As illustrated in FIGS. 1 and 2, for example, the reaction gas injectors 411 and 412 are respectively connected to an NH₃ gas supply source 45 via a pipe system in which a gas supply device 43 is positioned. The gas discharge ports 42 are respectively connected to the NH₃ gas supply source 45 via a pipe system having a gas supply device 44 positioned therein. The gas supply devices 43 and 44 are configured to control the supply/cutoff and the flow rate of the NH₃ gas from the gas supply source 45 to the reaction gas injectors 411 and 412 and the gas discharge ports 42, respectively. The reaction gas injectors 411 and 412 and the gas discharge ports 42 are also respectively connected to an Ar gas supply source (not shown).

If the flow rate of the NH₃ gas supplied to the reaction region R3 is too small, the progress of a nitriding process as described hereinbelow becomes slow and the deposition rate becomes low. Furthermore, even if the supply amount of the NH₃ gas is excessively increased, a proper deposition rate corresponding to the respective supply amount cannot be obtained, which is not advantageous in terms of cost. In addition, if the supply amount of the NH₃ gas is excessively increased, the amount of the NH₃ gas diffusing into the first modification region R2 and the second modification region R4 is increased, which may lower the modification effect of a film. Therefore, in this embodiment, the flow rate of the NH₃ gas supplied to the reaction region R3 may be, for example, 0.05 to 4.0 l/min

The first plasma forming unit 3A and the third plasma forming unit 3C are configured in the same manner as the second plasma forming unit 3B except that the gas discharge ports 42 are not formed.

In the vacuum vessel 11, an exhaust port is formed outside the rotary table 12 so as to face the reaction region R3. In this example, as illustrated in FIG. 2, for example, an exhaust port 51 is opened in the bottom portion of the vacuum vessel 11 substantially at the outer peripheral center of the rotary table 12 outside the reaction region R3 in the circumferential direction of the rotary table 12. An exhaust device 52 is connected to the exhaust port 51. For example, the exhaust port 51 is formed so as to be opened upward in the vessel body 11A of the vacuum vessel 11. An opening portion of the exhaust port 51 is located below the rotary table 12. An exhaust amount of gas from the exhaust port 51 by the exhaust device 52 is adjustable so that the vacuum atmosphere of a pressure corresponding to the exhaust amount is formed inside the vacuum vessel 11.

In the first modification region R2 and the second modification region R4, an extremely small amount of H₂ gas existing in the modification regions R2 and R4 is respectively activated by the first plasma forming unit 3A and the third plasma forming unit 3C. In this example, the extremely small amount of H₂ gas supplied to the first and second modification regions R2 and R4 is generated by the excitation of the NH₃ gas supplied to the reaction region R3 by the second plasma forming unit 3B.

As illustrated in FIG. 1, the film forming apparatus 1 includes a control part 10 provided with a computer. The control part 10 stores a program therein. The program incorporates a group of steps for transmitting a control signal to each part of the film forming apparatus 1 to control the operation of each part and for performing the film forming process as described hereinbelow. Specifically, the number of revolutions of the rotary table 12 by the rotation mechanism 13, the flow rate and the supply/cutoff of each gas by each gas supply device, the exhaust amount of gas by the exhaust device 52, the supply/cutoff of microwave from the microwave generator 37 to the antenna 31, the supply of power to the heater 15, and the like are controlled by the program. In other words, the control of the power supply for the heater 15 refers to the control of the temperature of the wafer W, and the control of the exhaust amount by the exhaust device 52 refers to the control of the internal pressure of the vacuum vessel 11. The program may be positioned on the control part 10 from a storage medium such as a hard disk, a compact disc, a magneto-optical disc, a memory card, or the like.

Hereinafter, the processing performed by the film forming apparatus 1 will be described. First, six wafers W are transferred to the respective recesses 14 of the rotary table 12 by the substrate transfer mechanism. The gate valve located in the transfer port 16 for transferring the wafers W is closed to hermetically seal the inside of the vacuum vessel 11. The wafers W mounted in the recesses 14 are heated to a predetermined temperature by the heater 15. Further, with the exhaust of gas from the exhaust port 51, the interior of the vacuum vessel 11 is kept in a vacuum atmosphere of a predetermined pressure. The rotary table 12 is rotated at, e.g., 10 to 30 rpm. Initially, in the adsorption region R1, the DCS gas supplied to the adsorption region R1 is adsorbed onto a certain wafer W.

Moreover, in the reaction region R3, the NH₃ gas is discharged from the reaction gas injectors 411 and 412 and the gas discharge ports 42 at a total flow rate of, e.g., 1.0 l/min, the Ar gas is discharged from the reaction gas injectors 411 and 412 and the gas discharge ports 42 at a total flow rate of 1.0 l/min, and the microwave is supplied from the microwave generator 37, in the second plasma forming unit 3B. The microwave supplied to the waveguide 33 passes through the slot holes 36A of the slot plate 36 and reaches the dielectric plate 32, and subsequently is supplied to the NH₃ gas discharged below the dielectric plate 32. As a result, the NH₃ gas is activated (excited) below the dielectric plate 32. By activating the NH₃ gas in this way, active species such as radicals containing nitrogen (N) are generated.

In the reaction region R3, the NH₃ gas is discharged from the reaction gas injectors 411 and 412 and the gas discharge ports 42, so that the NH₃ gas is evenly supplied into the reaction region R3. Then, the active species containing N and most of the NH₃ ions generated by the plasmarization of the NH₃ gas in the reaction region R3 flow out toward the exhaust port 51 formed outside the rotary table 12 in the reaction region R3. In this example, the atmosphere in the wide region within the process vessel 11 including the first modification region R2, the reaction region R3, and the second modification region R4, which is defined outside the adsorption region R1, is exhausted from the single exhaust port 51 formed outside the reaction region R3.

With the rotation of the rotary table 12, each wafer W passes through the reaction region R3, and the active species such as radicals containing N, which constitute plasma, are supplied to the surface of each wafer W. As a result, DCS adsorbed onto the surface of the wafer W is decomposed to generate a silicon nitride, thus forming a nitride layer (nitride film). Furthermore, by supplying the microwave from the microwave generator 37 in the first modification region R2 and the second modification region R4, an extremely small amount of H₂ gas is plasmarized.

In the gas supply/exhaust unit 2, the DCS gas is discharged from the gas discharge ports 21 at a predetermined flow rate and the Ar gas is discharged from the purge gas discharge port 23 at a predetermined flow rate. These gases are exhausted from the exhaust port 22. Furthermore, plasma of the NH₃ gas or the H₂ gas is continuously generated in the reaction region R3 and the first and second modification regions R2 and R4.

While the supply of each gas and the generation of plasma are performed in this manner, in order to maintain the internal pressure of the vacuum vessel 11 at a predetermined pressure, for example, 66.5 Pa (0.5 Torr) to 665 Pa (5 Torr), the pressure control is performed by a pressure regulation part located in an exhaust pipe (not shown) connected to the exhaust port 51. A manometer used to perform such a pressure control is located in, for example, the exhaust pipe.

The entire operation of the film forming apparatus 1 will now be summarized. The wafer W is located in the adsorption region R1 with the rotation of the rotary table 12. The DCS gas as a raw material gas containing silicon is supplied to and adsorbed onto the surface of the nitride film. Subsequently, the wafer W moves outward of the adsorption region R1 with the rotation of the rotary table 12. The purge gas is supplied to the surface of the wafer W so that the DCS gas adsorbed excessively onto the surface of the wafer W is removed. Furthermore, when the wafer W reaches the reaction region R3 with the rotation of the rotary table 12, the active species of the NH₃ gas contained in the plasma are supplied to the wafer W and react with the DCS gas so that an SiN layer is formed on the nitride film in an island shape.

In this manner, the wafer W is sequentially and repeatedly moved to the adsorption region R1, the first modification region R2, the reaction region R3, and the second modification region R4. When seen from the respective wafer W, the supply of the DCS gas, the supply of active species of the extremely small amount of H₂ gas, the supply of active species of the NH₃ gas, and the supply of active species of the extremely small amount of H₂ gas are sequentially repeated. As a result, each SiN layer formed in an island shape on the surface of the wafer W is modified and grows to extend in all directions. Even after that, the rotary table 12 continues to rotate so that SiN is deposited on the surface of the wafer W and a thin layer grows to form an SiN film.

That is to say, when the thickness of the SiN film is increased and the SiN film having a desired film thickness is formed, for example, the discharge and exhaust of each gas in the gas supply/exhaust unit 2 are stopped. In addition, the supply of the NH₃ gas and the supply of electric power in the second plasma forming unit 3B and the supply of electric power in the first and third plasma forming units 3A and 3C are respectively stopped, and the film forming process is completed. The wafer W which has been subjected to the film forming process is unloaded from the film forming apparatus 1 by the substrate transfer mechanism.

According to the film forming apparatus 1 described above, the amount of the H₂ gas to be supplied to the first modification region R2 and the second modification region R4 is extremely small in forming a nitride film of a raw material component using a raw material gas containing the raw material component and an ammonia gas. From the evaluation tests described hereinbelow, it was recognized that when the supply amount of the H₂ gas is extremely small, the concentration of hydrogen in the SiN film becomes lower and the concentration of chlorine in the SiN film becomes higher than when the supply amount of the H₂ gas is large. It is inferred from the forgoing that, by supplying a microwave to the extremely small amount of H₂ gas, the action of bonding H to dangling bonds in the SiN film and the action of removing Cl in the SiN film efficiently proceed, thus densifying the film and lowering the etching rate. Furthermore, in the reaction region R3, since the NH₃ gas is suppressed from being diluted with the H₂ gas, the nitriding process of active species (N radicals) of N may be performed while being less susceptible to the H₂ gas, and thus, the nitriding process is efficiently conducted. As can be understood from the evaluation tests described hereinbelow, by performing the nitriding process while being less susceptible to the H₂ gas in this way, the loading effect can be improved.

The mechanism of the present disclosure is presumed as follows. For example, in a system which supplies an H₂ gas to the first modification region R2 and the second modification region R4, H₂ radicals are generated in the first and second modification regions R2 and R4 by the activation of the H₂ gas, and flow out toward the reaction region R3. On the other hand, NH₃ ions, and NH₃ radicals with high energy and short lifespan, which are obtained by the activation of the NH₃ gas, exist in the reaction region R3. The H₂ radicals from the first and second modification regions R2 and R4 collide with the NH₃ radicals or the NH₃ ions so that the proportion of the NH₃ radicals with low energy and long lifespan is increased. The NH₃ radicals with low energy and long lifespan have lower reactivity (nitriding power) than the NH₃ ions or NH₃ radicals with high energy and short lifespan. This degrades the etching rate or the loading effect.

On the other hand, in the present disclosure, since the amount of the H₂ gas supplied to the first modification region R2 and the second modification region R4 is extremely small, the generated H₂ radicals are consumed for the modification process. Thus, the modification action proceeds in the first and second modification regions R2 and R4, while the NH₃ ions and the NH₃ radicals with high energy and short lifespan obtained by the activation of the NH₃ gas are efficiently utilized in the reaction region R3. Then, for example, the reaction proceeds with the NH₃ ions, the NH₃ radicals with high energy and short lifespan, and the NH₃ radicals with low energy and long lifespan. Thus, the film is densified and the etching rate is lowered, and the nitriding process is efficiently conducted and the loading effect is improved.

The loading effect referred to herein is an indicator of in-plane uniformity of film thickness when an SiN film is formed on a wafer in which a pattern is formed. Further, the improvement of the loading effect refers to the in-plane uniformity of film thickness, for example, a decrease in film thickness in the central portion of the wafer is improved. In this example, the loading effect is evaluated using the largest value among the values of the following equation Eq. (1) as an indicator value.

{((Bare film thickness)−(pattern film thickness)}/(bare film thickness)}×100 Eq. (1)

The term “bare film thickness” used herein denotes a film thickness when an SiN film is formed on a bare wafer on which no pattern is formed, and the term “pattern film thickness” used herein denotes a film thickness when an SiN film is formed on a pattern wafer on which a pattern whose surface area is three times that of the bare wafer is formed, under the same film forming conditions as those of the bare wafer. Each of the film thicknesses was measured at multiple positions on the diameter of the wafer W in the circumferential direction (X direction) of the rotary table 12. Each film thickness was obtained from the equation Eq. (1) at the respective measurement positions. It was confirmed that the smaller the indicator value of the loading effect is, the smaller the difference in film thickness between the bare wafer and the pattern wafer is, thus improving the loading effect.

In the aforementioned embodiment, the extremely small amount of H₂ gas obtained by decomposing the NH₃ gas in the reaction region R3 is used for modification. Thus, as described above, the modification effect is high and the loading effect can be improved. Accordingly, it can be said to be an advantageous configuration. It is presumed that the flow rate of the H₂ gas flowing into the first modification region R2 and the second modification region R4 due to the decomposition of the NH₃ gas performed in the reaction region R3 is small. In order to obtain a high generation efficiency of the H radical and a high modification effect, the flow rate of the H₂ gas may be 0.1 l/min or less.

In the aforementioned embodiment, the first and second modification regions R2 and R4 have been described to be arranged as modification regions, but one of the first and second modification regions R2 and R4 may be defined as a single modification region. Furthermore, in the aforementioned embodiment, the first and second modification regions R2 and R4 have been described to be respectively arranged at the upstream and downstream sides of the reaction region R3 in the rotational direction of the rotary table 12, but both the first and second modification regions R2 and R4 may be arranged at the upstream side of the reaction region R3 (i.e., the regions R1, R2, R4, and R3 may be arranged in the circumferential direction) or may be arranged at the downstream side of the reaction region R3 (i.e., the regions R1, R3, R2, and R4 may be arranged in the circumferential direction). In addition, the film forming apparatus 1 according to the present disclosure can be applied in, for example, forming a nitride film in which a raw material component is tungsten.

### (Evaluation Test 1)

In the film forming apparatus 1 illustrated in FIG. 1, an SiN film was formed using a DCS gas as a raw material gas in a state where an NH₃ gas and an Ar gas are discharged from the reaction gas injectors 411 and 412 and the gas discharge ports 42, and an H₂ gas is not supplied (Example). The total flow rate of the NH₃ gas discharged from the reaction gas injectors 411 and 412 is 0.6 l/min and the total flow rate of the Ar gas discharged from the reaction gas injectors 411 and 412 is 0.75 l/min, and the amount of the NH₃ gas supplied from the gas discharge ports 42 is 0.4 l/min and the flow rate of the Ar gas supplied from the gas discharge ports 42 is 0.25 l/min The SiN film was subjected to wet-etching using a hydrofluoric acid solution. An etching rate available at that time was evaluated. The SiN film was formed under the following conditions: the temperature of the rotary table 12: 450 degrees C., the number of revolutions of the rotary table 12: 30 rpm, and the processing pressure: 266 Pa. Furthermore, even when an H₂ gas of a flow rate of 4.25 l/min was supplied to each of the first modification region R2 and the second modification region R4 to form an SiN film under the same conditions as in the Example except for the foregoing conditions (Comparative example), the etching rate was evaluated in a similar manner

The results are shown in FIG. 4. The vertical axis represents a wet etching rate (WER), and a thermal oxide film is shown together with the SiN film of the Example and the SiN film of the Comparative example. Assuming that the etching rate when the thermal oxide film is wet-etched using a hydrofluoric acid solution under the same conditions is 1, the etching rate is illustrated as a relative value.

From FIG. 4, it was recognized that the etching rates of the SiN film of the Example and the SiN film of the Comparative example are remarkably lower than that of the thermal oxide film, and in particular, the etching rate of the SiN film of the Example is extremely low. Thus, it is understood that the modification reaction of the SiN film efficiently proceeds and the denseness is improved in the Example in which the H₂ gas is not supplied, compared with the Comparative example in which the H₂ gas is supplied.

### (Evaluation Test 2)

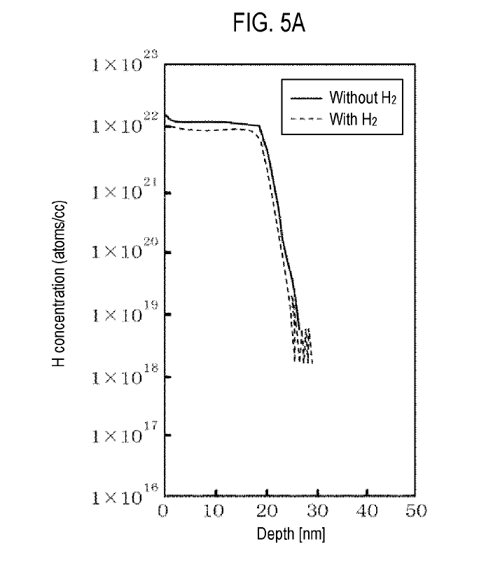

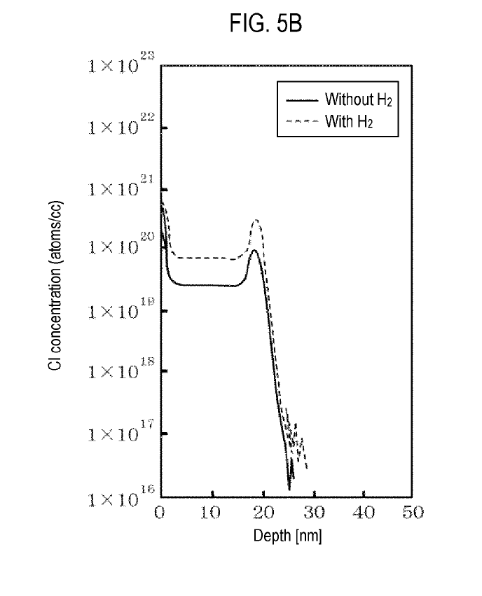

The concentrations of hydrogen and chlorine in a film were analyzed for the SiN film of the Example and the SiN film of the Comparative example by a secondary ion mass spectrometry (SINS). The results are shown in FIG. 5A. FIG. 5A shows the hydrogen concentration and FIG. 5B shows the chlorine concentration. In each of FIGS. 5A and 5B, the horizontal axis represents a depth of a film, and the vertical axis represents the hydrogen concentration (atoms/cc) and the chlorine concentration (atoms/cc). In both FIGS. 5A and 5B, data of the Example (without H₂) is indicated by the solid line, and data of the Comparative example (with H₂) is indicated by the dotted line.

As a result, it was recognized from FIG. 5A that the hydrogen concentration in the film is larger in the SiN film of the Example than in the Comparative example, and from FIG. 5B that the chlorine concentration in the film is smaller in the SiN film of the Example than in the Comparative example.

### (Evaluation Test 3)

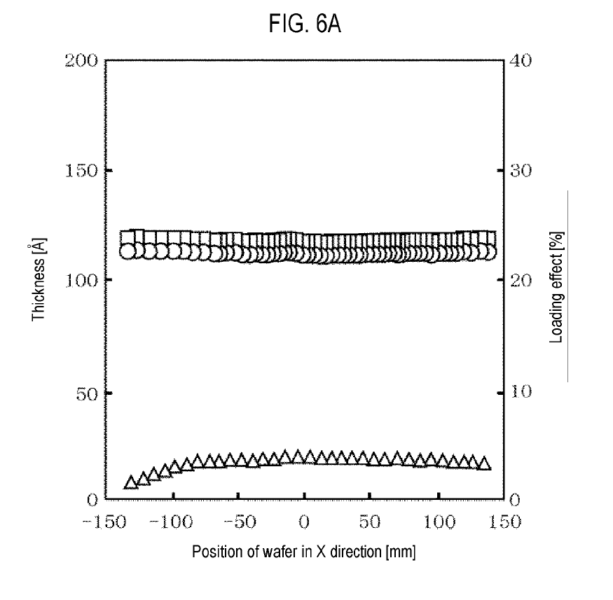

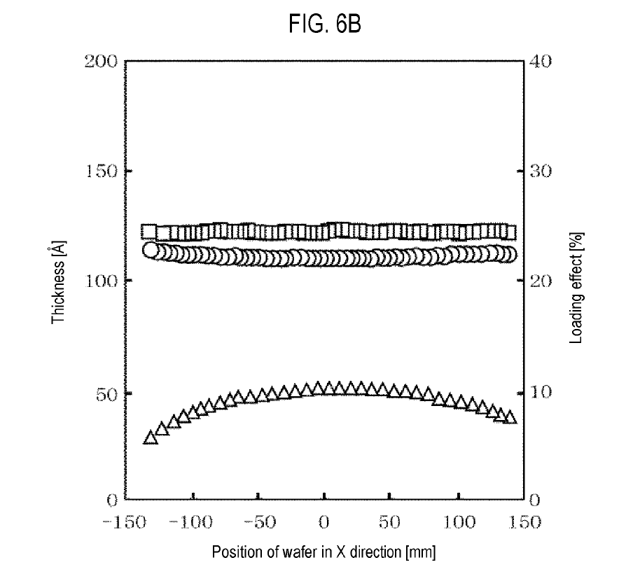

The loading effect was obtained for the SiN film of the Example and the SiN film of the Comparative example using the equation Eq. (1) by the aforementioned method. The results of the SiN film of the Example are shown in FIG. 6A, and the results of the SiN film of the Comparative example are shown in FIG. 6B. In each of FIGS. 6A and 6B, the vertical axis at the left side represents a film thickness of the SiN film, the vertical axis at the right side shows a loading effect, and the horizontal axis shows positions on the diameter of the wafer W in the X direction. Here, 0 denotes the center of the wafer W, −150 and 150 denote outer edges of the wafer W in the X direction, respectively. In FIGS. 6A and 6B, the film thicknesses of the pattern wafer are plotted using the symbol ο, the film thicknesses of the bare wafer are plotted using the symbol □, and the loading effects are plotted using the symbol Δ.

As a result, it was recognized that the SiN film of the Example has better film thickness in-plane uniformity of the pattern wafer than the SiN film of the Comparative example, and for the pattern wafer of the Comparative example, the film thickness at the center of the wafer is smaller than at the periphery thereof. Furthermore, it was recognized that the maximum value of the loading effect of the SiN film of the Example was 3.8%, the maximum value of the loading effect of the SiN film of the Comparative example was 10.3%, and thus the numerical value of the loading effect of the SiN film of the Example was relatively small, which improves the loading effect.

### (Evaluation Test 4)

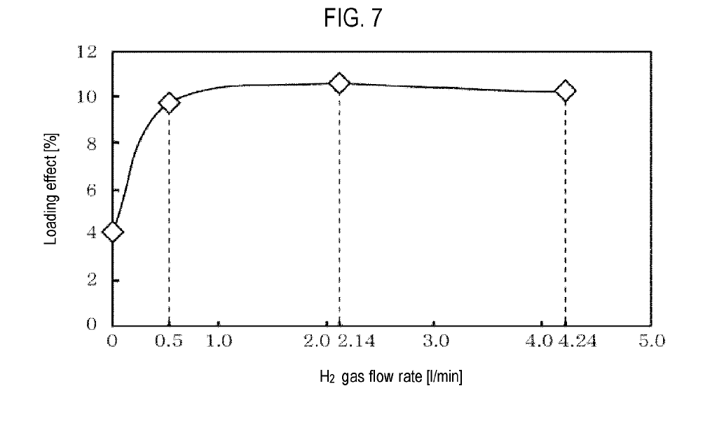

An SiN film was formed by changing the amount of an H₂ gas supplied to the first and second modification regions R2 and R4, and the loading effect of each SiN film was evaluated. The SiN film was formed by changing the total supply amount of the H₂ gas to 0 l/min, 0.5 l/min, 2.14 l/min, and 4.24 l/min Other film forming conditions were set similarly to those of the Example. The loading effect was evaluated using the equation Eq. (1) in the manner described above, and the maximum value was obtained. The results are shown in FIG. 7. In FIG. 7, the vertical axis represents the loading effect, and the horizontal axis represents the supply amount of the H₂ gas.

As a result, it was recognized that when the supply amount of the H₂ gas is 0, the maximum value of the loading effect was 3.8%, whereas when the supply amount of the H₂ gas becomes 0.5 l/min, the loading effect was 9% and when the supply amount of the H₂ gas is more than 0.5 l/min, the loading effect was more than 10%, which remains roughly flat. In addition, it is presumed that, when each of the flow rates of the H₂ gas supplied to the first and second modification regions R2 and R4 is larger than 0 and not more than 0.1 l/min, the loading effect of not more than 1.5 times the maximum value of the loading effect of the film available under a condition in which the H₂ gas is not supplied is obtained.

According to the present disclosure in some embodiments, in forming a nitride film of a raw material component using a raw material gas containing the raw material component and an ammonia gas, the amount of a hydrogen gas to be supplied to a first modification region and a second modification region is set to be extremely small. Therefore, in a reaction region, a nitriding process using the ammonia gas is performed while being less susceptible to the hydrogen gas. This enhances the nitriding efficiency and improves the loading effect. As a result, it is possible to form a high-quality nitride film with a low etching rate while improving the loading effect.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming apparatus for forming a nitride film of a raw material component on a substrate inside a vacuum vessel by revolving a rotary table on which the substrate is disposed and supplying a raw material gas containing the raw material component and an ammonia gas used as a reaction gas to regions separated from each other in a circumferential direction of the rotary table, the apparatus comprising:
a raw material gas supply part facing the rotary table, and having a first discharge port that discharges the raw material gas, an exhaust port that surrounds the first discharge port and a second discharge port that surrounds the exhaust port and discharges a purge gas;
a reaction region spaced apart from the raw material gas supply part in the circumferential direction of the rotary table and in which the nitride film is nitrided;
a modification region spaced apart from the reaction region in the circumferential direction of the rotary table, and in which the nitride film is modified with a hydrogen gas;
a first plasma generating part provided in the modification region and a second plasma generating part provided in the reaction region, and configured to activate a gas existing in each of the modification region and the reaction region;
a reaction gas supply part configured to supply the ammonia gas to the reaction region; and
an exhaust port configure to evacuate an interior of the vacuum vessel,
wherein a flow rate of the hydrogen gas supplied to the modification region is greater than 0 and not more than 0.1 l/min.

2. The apparatus of claim 1, wherein the exhaust port is located at a position where an atmosphere of the modification region and an atmosphere of the reaction region are simultaneously exhausted, and
the hydrogen gas supplied to the modification region is generated by exciting the ammonia gas supplied to the reaction region by the second plasma generating part.

3. The apparatus of claim 2, wherein the exhaust port is located at a position facing the reaction region and outside the rotary table in a plan view.

4. The apparatus of claim 1, wherein a flow rate of the ammonia gas supplied to the reaction region is 0.05 to 4.0 l/min.

5. The apparatus of claim 1, wherein the modification region includes a first modification region and a second modification region spaced apart from each other in the circumferential direction of the rotary table, and
the first plasma generating part is positioned in a corresponding relationship with each of the first modification region and the second modification region.
